(19) United States
(12) Patent Application Publication
(10) Pub. No.: US 2017/0062706 A1
(43) Pub. Date: Mar. 2, 2017

(54) MAGNETORESISTIVE ELEMENT AND METHOD OF MANUFACTURING THE SAME

(71) Applicant: KABUSHIKI KAISHA TOSHIBA, Tokyo (JP)

(72) Inventors: Koji YAMAKAWA, Yokkaichi Mie (JP); Shinichi KANOO, Yokkaichi Mie (JP)

(73) Assignee: KABUSHIKI KAISHA TOSHIBA, Tokyo (JP)

(21) Appl. No.: 15/067,938

(22) Filed: Mar. 11, 2016

Related U.S. Application Data
(60) Provisional application No. 62/212,493, filed on Aug. 31, 2015.

(51) Int. Cl. H01L 43/08; H01L 43/10; G11C 11/16; H01L 43/02; H01L 43/12

(52) U.S. Cl. CPC H01L 43/08; H01L 43/02; H01L 43/12; G11C 11/161; H01L 43/10

(57) ABSTRACT

According to one embodiment, a magnetoresistive element includes a first layer including a material as one of a nitride, an oxide, a carbide and a boride, a second layer as a magnetic layer on the first layer, a third layer as a nonmagnetic layer on the second layer, and a fourth layer as a magnetic layer on the third layer, magnetization directions of the second and fourth layers being a perpendicular direction in which the first, second, third and fourth layers are stacked. The first layer is thinner than a crystal grain size of the first layer in the perpendicular direction.

### CROSS-REFERENCE TO RELATED APPLICATIONS

This application claims the benefit of U.S. Provisional Application No. 62/212,493, filed Aug. 31, 2015, the entire contents of which are incorporated herein by reference.

### FIELD

Embodiments described herein relate generally to a magnetoresistive element and a method of manufacturing the same.

### BACKGROUND

A magnetoresistive element comprises a storage layer of variable magnetization, a reference layer of constant magnetization, and a nonmagnetic layer (tunnel barrier layer) between them. In a perpendicular-magnetization magnetoresistive element where the magnetization directions of a storage layer and a reference layer are perpendicular to the surfaces of the layers stacked on each other, it is advantageous to enhance the perpendicular magnetic anisotropy of the storage and reference layers, in order to enhance the characteristics (such as the MR ratio, magnetization reversal current, retention) of the magnetization. element.

### BRIEF DESCRIPTION OF THE DRAWINGS

FIG. 1 is a cross-sectional view showing a magnetoresistive element according to a first embodiment.

FIG. 2 is a cross-sectional view showing a magnetoresistive element according to a second embodiment.

FIG. 3 is a cross-sectional view showing a magnetoresistive element according to a third embodiment.

FIGS. 4A, 4B, 40, 5A, 5B and 50 are cross-sectional views showing a magnetoresistive element according to a fourth embodiment.

FIGS. 6 to 9 are cross-sectional views showing an example of a method of manufacturing the structure of FIG. 3.

FIG. 10 is a plan view showing a magnetic memory as an application example.

FIG. 11 is a cross-sectional view taken along line XI-XI of FIG. 10.

FIG. 12 is a cross-sectional view showing a first. magnetoresistive element. example.

FIG. 13 is a cross-sectional view showing a second magnetoresistive element example.

FIG. 14 is a cross-sectional view showing a third magnetoresistive element example.

FIG. 15 is a cross-sectional view showing a fourth magnetoresistive element example.

FIG. 16 is a cross-sectional view showing a fifth magnetoresistive element example.

FIG. 17 is a cross-sectional view showing a sixth magnetoresistive element example.

### DETAILED DESCRIPTION

In general, according to one embodiment, a magnetoresistive element comprises: a first layer including a material as one of a nitride, an oxide, a carbide and a boride; a second layer as a magnetic layer on the first layer; a third layer as a nonmagnetic layer on the second layer; and a fourth layer as a magnetic layer on the third layer, magnetization directions of the second and fourth layers being a perpendicular direction in which the first, second, third and fourth layers are stacked. The first layer is thinner than a crystal grain size of the first layer in the perpendicular direction.

### Embodiments

Embodiments described below are related to a so-called perpendicular-magnetization magnetoresistive element.

The perpendicular-magnetization magnetoresistive element comprises a first magnetic layer (storage layer) of perpendicular and variable magnetization, a second magnetic layer (reference layer) of perpendicular and constant magnetization, and a nonmagnetic layer (tunnel barrier layer) interposed therebetween.

Perpendicular magnetization means magnetization exerted in a perpendicular direction, namely, exerted along an axis along which layers are stacked. In other words, perpendicular magnetization means magnetization exerted perpendicularly with respect to the surfaces (film surface) of the layers. The film surfaces mean interfaces between the first magnetic layer, the nonmagnetic layer and the second magnetic layer.

Further, constant magnetization means that the direction of magnetization does not change before and after writing, and variable magnetization means that. the direction of magnetization changes before and after writing. Writing means spin transfer writing in which torque is imparted to the magnetization of the first magnetic layer by applying a spin-injection. current (spin-polarized electrons) to a magnetoresistive element.

In such a magnetoresistive element, it is effective for enhancing the characteristics of the magnetoresistive element to enhance the perpendicular magnetic anisotropy of the first and second magnetic layers.

For instance, in a magnetoresistive element wherein MgO is used as the material of the nonmagnetic layer, and CoFeB is used as the material of the first and second magnetic layers, the perpendicular magnetic anisotropy of the first and second magnetic layers occurs at the interface between the first magnetic layer and the nonmagnetic layer and at the interface between the second magnetic layer and the nonmagnetic layer. That is, the first and second magnetic layers in an amorphous state are influenced by the crystal structure and orientation of the nonmagnetic layer during, for example, a heat treatment, whereby they are transformed into a crystal structure.

However, the first and second magnetic layers cannot have a sufficient perpendicular magnetic anisotropy only from the perpendicular magnetic anisotropy that occurs at the interface between the first magnetic layer and the nonmagnetic layer and at the interface between the second magnetic layer and the nonmagnetic layer.

Therefore, the embodiments described below are related to a technique of developing a perpendicular magnetic anisotropy not only on first surfaces of the first and second magnetic layers close to the respective nonmagnetic layers, but also on second surfaces of the same away from the respective nonmagnetic layers. Furthermore, a mechanism for applying perpendicular tensile stress to the second surfaces of the first and second magnetic layers, or a mechanism for providing an equivalent effect, is employed as a method of developing a perpendicular magnetic anisotropy.

### First Embodiment

A first embodiment is related to a technique of enhancing the perpendicular magnetic anisotropy of a magnetic layer on a foundation layer in the magnetoresistive element, by using, as the material of the foundation layer, a material having perpendicular internal tensile stress or a material having an effect equivalent to it. The internal tensile stress is also called residual tensile stress.

FIG. 1 shows a magnetoresistive element according to the first embodiment.

The magnetoresistive element MTJ shown in FIG. 1 comprises a foundation layer 10a, a first magnetic layer 11 on the foundation layer 10a, a nonmagnetic layer (tunnel barrier layer) 12 on the first magnetic layer 11, and a second magnetic layer 13 on the nonmagnetic layer 12. One of the first and second magnetic layers 11 and 13 is a storage layer of variable magnetization, and the other is a reference layer of constant magnetization.

The foundation layer 10a comprises a material having perpendicular internal tensile stress, or a material having an effect equivalent to it. The foundation layer 10a may be in a crystal state or an amorphous state. In this case, the foundation layer 10a is in a perpendicularly tensile state, and hence stress of returning to an original state occurs therein. That is, the foundation layer 10a applies perpendicular tensile stress to the second surface of the first magnetic layer 11 on the foundation layer 10a, which is opposite to the first surface close to the nonmagnetic layer 12.

In a manufacturing process of the magnetoresistive element, the first and second magnetic layers 11 and 13 are transformed by a heat treatment from an amorphous state to a crystal state.

At this time, the first and second magnetic layers 11 and 13 are influenced by the crystal structure and orientation of the nonmagnetic layer 12, and are transformed into a crystal structure having perpendicular magnetic anisotropy. Moreover, since tensile stress is applied from the foundation layer 10a to the first magnetic layer 11, the perpendicular magnetic anisotropy of the first magnetic layer 11 is enhanced. In addition, if the foundation layer 10a has the similar crystal structure or crystal orientation as the nonmagnetic layer 12, the crystal structure or orientation of the first magnetic layer 11 can be controlled from above and below, whereby the perpendicular magnetic anisotropy of the first magnetic layer 11 is further enhanced.

For example, in the case of the nonmagnetic layer 12 is MgO with a (001)-oriented NaCl-crystal structure, the foundation layer 10a is GaN, AlN, or a mixture thereof with a (0001)-oriented hexagonal close-packed (hcp) crystal structure or (0001)-oriented wurtzite crystal structure.

Since thus, the perpendicular magnetic anisotropy of the first magnetic layer 11 can be enhanced, the characteristics (MR ratio, flux reversal current, retention, etc.) of the magnetoresistive element can be improved.

### Second Embodiment

A second embodiment is related to a technique of enhancing the perpendicular magnetic anisotropy of a magnetic layer under an upper layer in the magnetoresistive element, by using, as the material of the upper layer, a material having perpendicular internal tensile stress or a material having an effect equivalent to it.

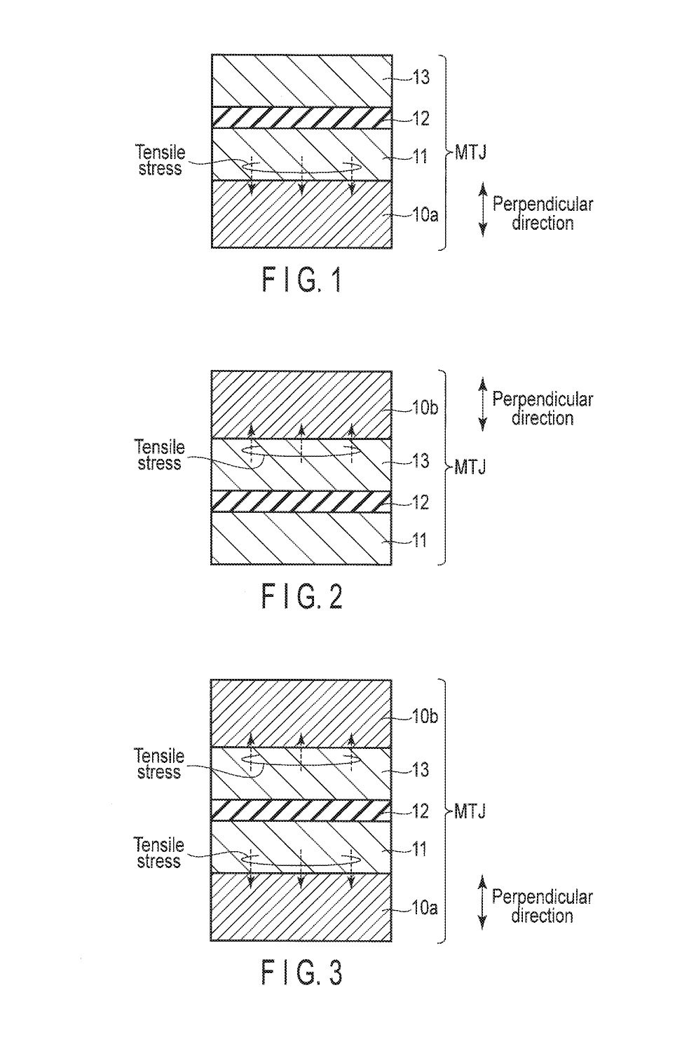

FIG. 2 shows a magnetoresistive element according to the second embodiment.

The magnetoresistive element MTJ shown in FIG. 2 comprises a first magnetic layer 11, a nonmagnetic layer (tunnel barrier layer) 12 on the first magnetic layer 11, a second magnetic layer 13 on the nonmagnetic layer 12, and an upper layer 10b on the second magnetic layer 13. One of the first and second magnetic. layers 11 and 13 is a storage layer of variable magnetization, and the other is a reference layer of constant magnetization.

The upper layer 10b comprises a material having perpendicular internal tensile stress, or a material having an effect equivalent to it. The upper layer 10b may be in a crystal state or an amorphous state. In this case, the upper layer 10b is in a perpendicularly tensile state, and hence stress of returning to an original state occurs therein. That is, the upper layer 10b applies perpendicular tensile stress to the second surface of the second magnetic layer 13 just below the upper layer 10b, which is opposite to the first surface close to the nonmagnetic layer 12.

In a manufacturing process of the magnetoresistive element, the first and second magnetic layers 11 and 13 are transformed by a heat treatment from an amorphous state to a crystal state.

At this time, the first and second magnetic layers 11 and 13 are influenced by the crystal structure and. orientation of the nonmagnetic layer 12, and are transformed into a crystal structure having a perpendicular magnetic anisotropy. Moreover, since tensile stress is applied from the upper layer 10b to the second magnetic layer 13, the perpendicular magnetic anisotropy of the second magnetic layer 13 is enhanced. In addition, if the upper layer 10b has the similar crystal structure or crystal orientation as the nonmagnetic layer 12, the crystal structure or orientation of the second magnetic layer 13 can be controlled from above and below, whereby the perpendicular magnetic anisotropy of the second magnetic layer 13 is further enhanced.

For example, in the case of the nonmagnetic layer 12 is MgO with a (001)-oriented NaCl-crystal structure, the upper layer 10b is GaN, AlN, or a mixture thereof with a (0001)-oriented hexagonal close-packed (hcp) crystal structure or (0001)-oriented wurtzite crystal structure.

Since thus, the perpendicular magnetic anisotropy of the second magnetic layer 13 can be enhanced, the characteristics (MR ratio, flux reversal current, retention, etc.) of the magnetoresistive element can be improved.

### Third Embodiment

A third embodiment is a combination of the first and second embodiments.

FIG. 3 shows a magnetoresistive element according to the third embodiment.

The magnetoresistive element MTJ shown in FIG. 3 comprises a foundation. layer 10a, a first magnetic layer 11 on the foundation layer 10a, a nonmagnetic layer (tunnel barrier layer) 12 on the first magnetic layer 11, a second magnetic layer 13 on the nonmagnetic layer 12, and an upper layer 10b on the second magnetic layer 13. One of the first and second magnetic layers 11 and 13 is a storage layer of variable magnetization, and the other is a reference layer of constant magnetization.

The foundation layer 10a and the upper layer 10h comprise a material having perpendicular internal tensile stress, or a material having an effect equivalent to it. The upper layer 10b and the upper layer 10b may be in a crystal state or an amorphous state.

Since in the third embodiment, both the first and second magnetic layers 11 and 13 can be enhanced in perpendicular magnetic anisotropy, the characteristics (MR ratio, flux reversal current, retention, etc.) of the magnetoresistive element can be enhanced.

### Fourth Embodiment

A fourth embodiment is related to control of internal stress.

in order to enhance the perpendicular magnetic anisotropy of the first and second magnetic layers 11 and 13, it is important to control stress applied to the first or second magnetic layer 11 or 13, i.e., to control internal stress of the foundation layer 10a and/or the upper layer 10b.

In the fourth embodiment, the materials, the structure, etc., are controlled so that the foundation layer 10a or the upper layer 10b will have internal tensile stress or an effect equivalent thereto.

Examples of Materials

Materials having internal tensile stress or an effect equivalent thereto include nitrides, oxides, carbides or borides.

As nitrides, GaN, AlN, TiN, TaN, NM, MoN, NbN, SiN, HfN, ZrN BN, etc., are desirable. The composition ratios of these compounds may be changed suitably.

As oxides, FeO, ZnO, InSnO (Indium tin oxide: ITO), TiO, MnO, SnO, InO, etc. are desirable. The composition ratio of these compounds may be changed suitably. Further, FeO (its composition ratio is variable) may be used as an oxide. FeO can exhibit an effect equivalent to internal tensile stress because of bonding of Fe and O.

As carbides, WC, TiC, TaC, SiC, etc., are desirable. The composition ratios of these compounds may be changed suitably.

As borides, TiB, TaB, WB, MoB, NbB, AlB, SiB, HfB, ZrB, etc., are desirable. The composition ratios of these compounds may be changed suitably.

These materials have a small friction coefficient, attenuation coefficient, and dumping constant. Accordingly, if the foundation layer 10a or the upper layer 10b is formed of these materials, write current can be reduced. Moreover, lithe foundation layer 10a or the upper layer 10b is made thin, write current can be further reduced, since at this time, the layer is reduced in resistance.

Structural Example

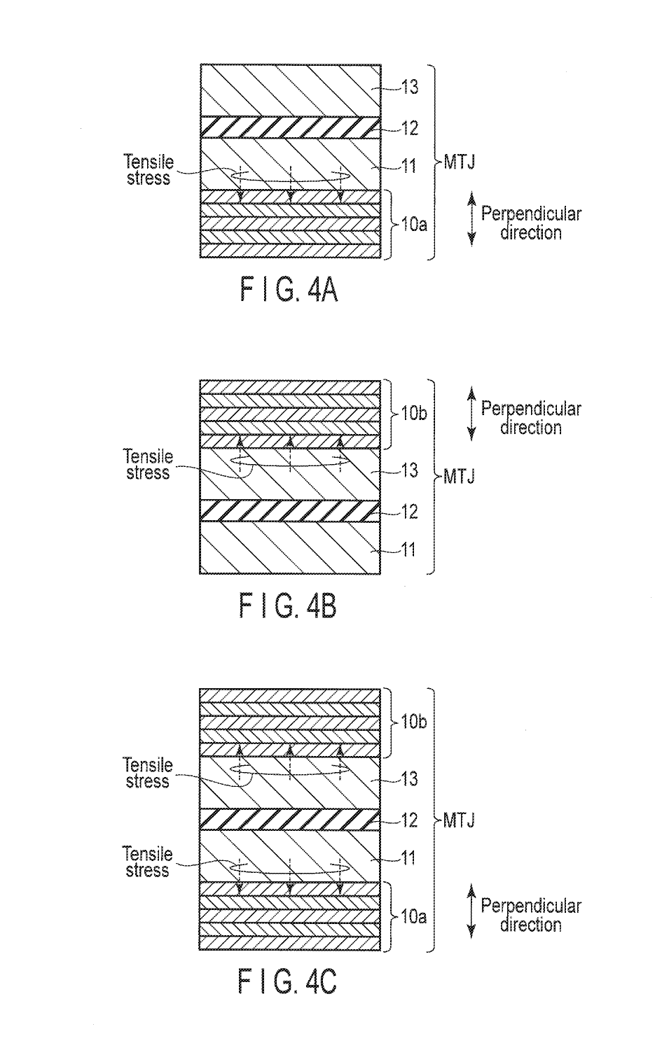

The structures shown in FIGS. 4A, 4B and 4C are characterized in that the foundation layer 10a or the upper layer 10b has a laminated structure comprising a plurality of layers.

In order to control the entre internal stress of the foundation layer 10a or the upper layer 10b, the plurality of layers differ from each other at least in state (crystalline or amorphous), material, composition ratio or conductivity.

By virtue of this structure, the entire internal stress of the foundation layer 10a or the upper layer 10b can be controlled to optimize the perpendicular magnetic anisotropy of the first and second magnetic layers 11 and 13.

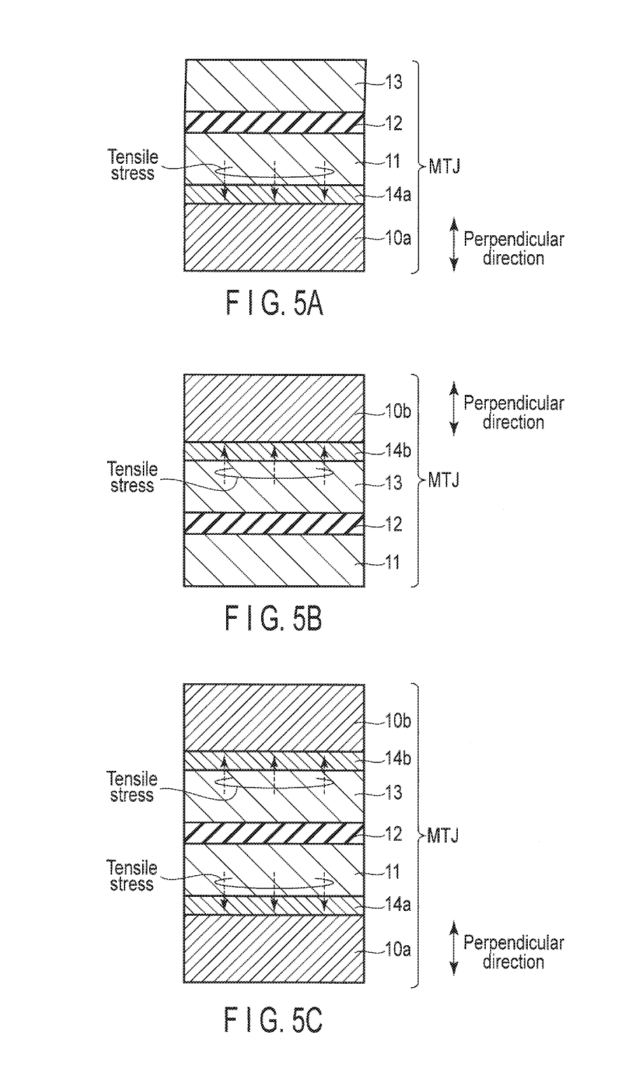

The structures shown in FIGS. 5A, 5B and 5C are characterized in that intermediate layers 14a and 14b containing Fe are interposed between the foundation layer 10a and the first magnetic layer 11, or between the upper layer 10b and the second magnetic layer 13.

Intermediate layers 14a and 14b are, for example, Fe layers or FeO layers. The Fe layer is oxidized during a manufacturing process of the magnetoresistive element, whereby part of the Fe layer is transformed into an FeO layer. The FeO layer can exhibit an effect equivalent to internal tensile stress because of bonding of Fe and O. It is desirable to form intermediate layers 14a and 14b to a thickness of 1 nm or less.

By virtue of this structure, tensile stress applied by intermediate layers 14a and 14b to the first and second magnetic layers 11 and 13 can be controlled to optimize the perpendicular magnetic anisotropy of the first and second magnetic layers 11 and 13.

(Manufacturing Method)

A description will be given of a method of manufacturing the magnetoresistive elements according to the above-described embodiments.

In particular, a method of manufacturing the structure of the third embodiment, which is a combination of the first and second embodiments, will be described. The structures of the first and second embodiments can be easily conceived from the manufacturing method described below.

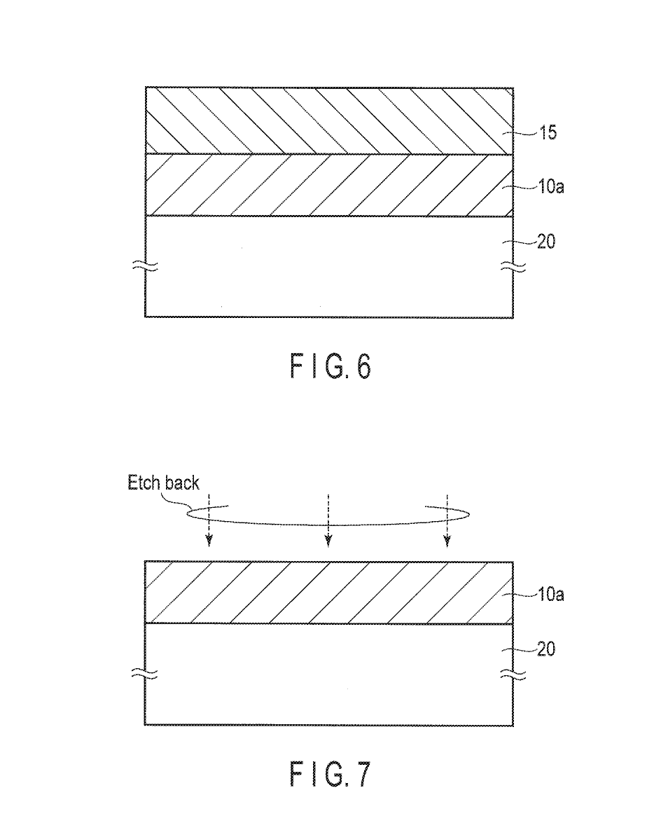

First, as shown in FIG. 6, the foundation layer 10a (formed of, for example, GaN) is formed on a semiconductor substrate 20. In the example described below, no layers are provided between the foundation layer 10a and the semiconductor substrate 20, for simplifying the description. However, layers may exist therebetween.

Subsequently, a cap layer 15 is formed on the foundation layer 10a. Both the foundation layer 10a and the cap layer 15 are formed to a thickness of several nanometers, for example, about 5 nm.

Subsequently, a heat treatment is performed to crystallize the foundation layer 10a. The heat treatment is performed in a vacuum or inert gas for, for example, about one minute. The temperature of the heat treatment is set higher than the crystallization temperature of the material of the foundation layer 10a.

When the foundation layer 10a is thus crystallized, it exhibits good orientation. This is desirable to enhance the magnetic anisotropy of the magnetic layers on the foundation layer 10a. However, the foundation. layer 10a may have an amorphous portion.

For crystallization of the foundation layer 10a, the cap layer 15 should be formed as follows:

For example, if the foundation layer 10a is formed of GaN, it is desirable to form the cap layer 15 of Hf, GaN, Ru, Ta, Ti or Zr. It is also desirable to form the cap layer 15 of the same material as the tunnel barrier layer of the magnetoresistive element. For instance, if the tunnel barrier layer of the magnetoresistive element is formed of MgO, the cap layer 15 is also formed of MgO.

In this case, the foundation layer 10a (formed of, for example, GaN) in an amorphous state is influenced by the crystal structure (orientation) of MgO of the cap layer 15, and is crystallized into a crystal structure (orientation) near the crystal structure of MgO. This means that the magnetic layers are influenced by the crystal structure of MgO or a crystal structure close to it from both the tunnel barrier layer side and the foundation layer 10a side. That is, the orientation of the magnetic layers can be easily made to coincide with the orientation of MgO.

Moreover, the foundation layer 10a is changed by the heat treatment into a crystal structure having internal tensile stress. In order to, for example, enhance the perpendicular magnetic anisotropy of magnetic layers described later, it is desirable to set the internal tensile stress to 300 MPa or more.

To secure such internal tensile stress, the internal tensile stress of the foundation layer 10a may be controlled by the following process technique, in addition to the control of the material of the foundation layer 10a.

For example, the internal tensile stress of the foundation. layer 10a can be controlled by performing above-mentioned heat treatment in a gaseous atmosphere containing nitrogen, oxygen, carbon or boron. That is, by adjusting the concentration (in the gaseous atmosphere) of nitrogen, oxygen, carbon or boron during the heat treatment, the composition ratio of the materials of the foundation layer 10a can be changed to thereby adjust its internal tensile stress.

If the foundation layer 10a is formed of a nitride, it is desirable to perform the heat treatment in an atmosphere of nitrogen. Similarly, if the foundation layer 10a is formed of an oxide, a carbide or a horde, it is desirable to perform the heat treatment in an atmosphere of oxygen, carbon or boron. Alternatively, it is also possible to control the internal tensile stress by performing a heat treatment in an atmosphere of an element different from the element contained in the foundation layer 10a.

Further, when forming the foundation layer 10a, the concentration of nitrogen, oxygen, carbon or boron contained in the foundation layer 10a may be controlled beforehand.

For example, if the foundation. layer 10a is formed of a nitride, it is possible to control the internal tensile stress by making the concentration of nitrogen in the foundation layer 10a greater than that of the other constituent, and then controlling the amount of nitrogen discharged from the foundation layer 10a during a heat treatment. Similarly, if the foundation layer 10a is formed of an oxide, a carbide or a boride, the same control is possible by making the concentration of oxygen, carbon or boron in the foundation layer 10a greater than that of the other constituent.

In contrast, if the foundation layer 10a is formed of a nitride, it is possible to control the internal tensile stress by making the concentration of nitrogen in the foundation layer 10a less than that of the other constituent, and then controlling the amount of nitrogen injected into the foundation layer 10a during a heat treatment. Similarly, if the foundation layer 10a is formed of an oxide, a carbide or a boride, the same control is possible by making the concentration of oxygen, carbon or boron in the foundation layer 10a less than that of the other constituent.

In the above-mentioned heat treatment, the cab layer 15 may not be formed. In this case, the foundation layer 10a is crystallized without the cap layer 15.

Furthermore, if the foundation layer 10a has a structure as shown in FIG. 4C, it is sufficient if the above-mentioned foundation layer 10a is replaced with a plurality of layers forming the foundation layer 10a of FIG. 4C.

Next, the cap layer 15 and the foundation layer 10a are etched by etch back, thereby leaving a foundation layer 10a of a predetermined thickness, for example, about 1 nm, as shown in FIG. 7.

If the foundation layer 10a is made perpendicularly thinner than the grain size thereof, the foundation layer 10a can have a sufficiently flat surface with its orientation maintained. Where, shown in FIGS. 6 and 7, the grain size means an average of grain sizes S0, S1, S2, . . . of crystals (broken line) of the foundation layer 10a in the perpendicular direction.

Further, in a case where intermediate layer 14a exists on the foundation layer 10a as in the structure of FIG. 5C, it may be formed on the foundation layer 10a after the etchback.

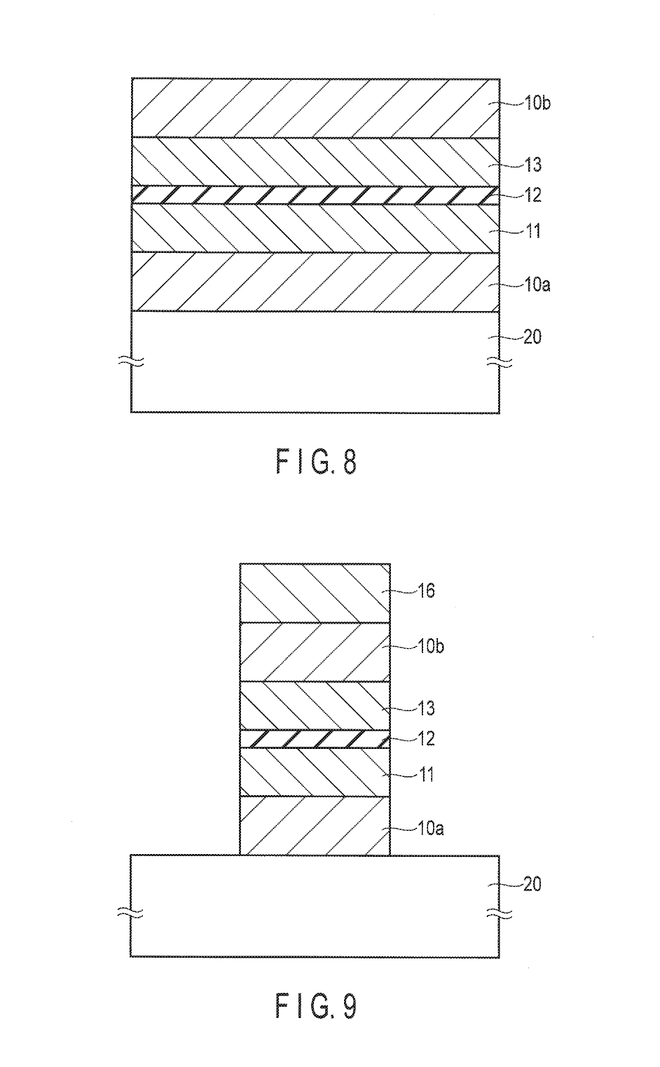

Next, as shown in FIG. 8, the first magnetic layer 11, the nonmagnetic layer 12, the second magnetic layer 13 and the upper layer 10b are formed on the foundation layer 10a.

Thereafter, a heat treatment for crystallizing the first and second magnetic layers 11 and 13 is performed.

This heat treatment is performed for, for example, about one minute in a vacuum or inert gas, like the heat treatment for crystallizing the foundation layer 10a. The temperature of the heat treatment is set to, for example, about 400° C. higher than the crystallization temperature of the materials in the first and second magnetic layers 11 and 13.

The first and second magnetic layers 11 and 13 are influenced by the crystal structure and orientation. of the nonmagnetic layer 12, and are changed into a crystal structure having perpendicular magnetic anisotropy.

If, for example, the first and second magnetic layers 11 and 13 are formed of CoFeB of an amorphous state, the nonmagnetic layer 12 is formed of MgO having an NaCl structure oriented along {001}-plane, CoFeB of the amorphous state is transformed into a BCC structure oriented along {001}-plane by a heat treatment.

At this time, since tensile stress is applied to the first magnetic layer 11 by the foundation layer 10a, and tensile stress is applied to the second magnetic layer 13 by the upper layer 10b, the perpendicular magnetic anisotropy of the first and second magnetic layers 11 and 13 is enhanced.

Furthermore, if the foundation layer 10a and the upper layer 10b have a crystal structure and orientation equivalent to those of the nonmagnetic layer 12, the crystal structure and orientation of each of the first and second magnetic layers 11 and 13 can be controlled from above and below, whereby the perpendicular magnetic anisotropy of the first and second magnetic layers 11 and 13 are further enhanced.

If the upper layer 10b has a structure as shown in FIG. 4C, it is sufficient if the above-mentioned upper layer 10b is replaced with a plurality of layers forming the upper layer 10b of FIG. 4C.

Further, in a case where intermediate layer 14b exists on the upper layer 10b as in the structure of FIG. 5C, it is sufficient if the upper layer 10b is formed on intermediate layer 14b after intermediate layer 14b is formed on the second magnetic layer 13. Lastly, as shown in FIG. 9, a hard mask layer (for example, a metal layer) 16 is formed on the upper layer 10b. The hard mask layer 16 is used as a mask, whereby the upper layer 10b, the second magnetic layer 13, the nonmagnetic layer 12, the first magnetic layer 11, and the foundation layer 10a, are sequentially etched by ion beam etching.

As a result, a magnetoresistive element as shown in FIG. 3 is completed.

(Example of Application)

A description will now be given of an application example of the above-mentioned magnetoresistive element.

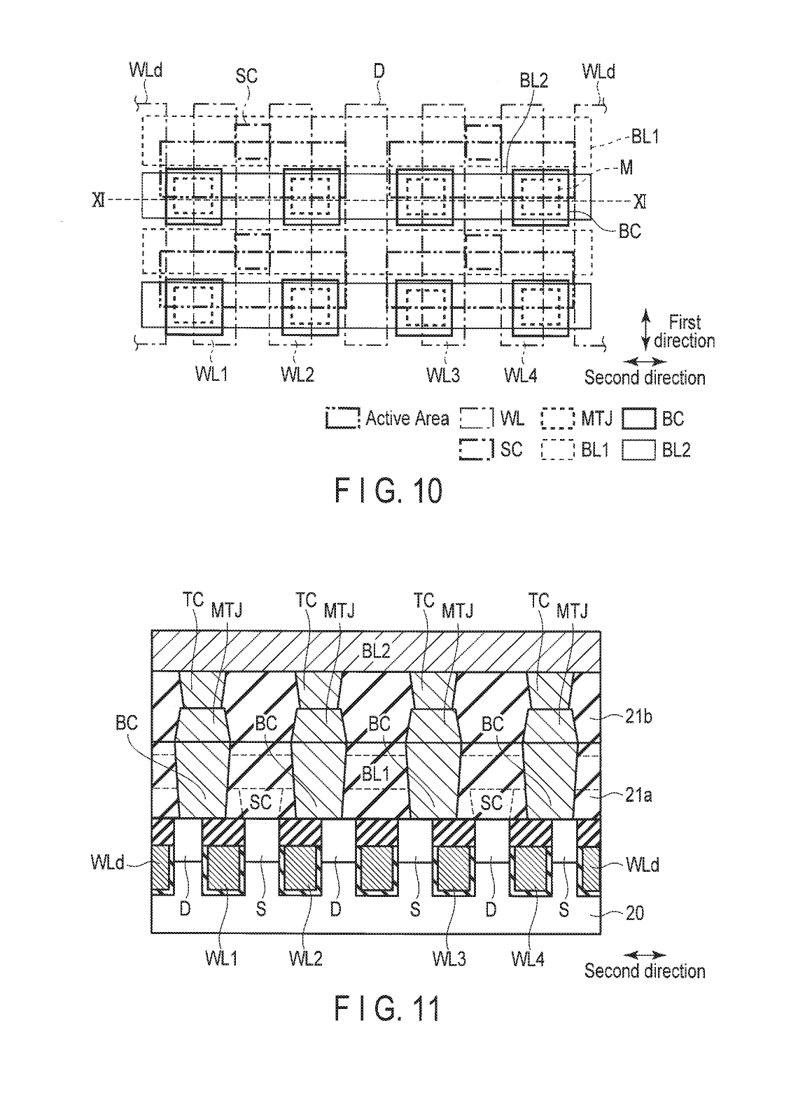

FIG. 10 shows a memory cell array of a magnetic memory. FIG. 11 is a cross-sectional view taken along line XI-XI of FIG. 10.

Word lines WL1, WL2, WL3 and WL4 are arranged in a semiconductor substrate (for example, a silicon substrate) 20, and are extended in a first. direction. Word lines WL1, WL2, W13 and WL4 function as gate electrodes of select transistors. That is, the gate electrode of each select transistor is of a buried gate type.

Dummy word lines WLd are intermingled among word lines WL1, WL2, WL3 and WL4. A select transistor that uses a dummy word line WLd as a gate electrode functions as an element-isolation transistor for dividing, into a plurality of areas, an active area extending in a second direction.

One (S) of two impurity areas S and D included in each of select transistors, which use word lines WL1, WL2, WL3 and WL4 as respective gate electrodes, is connected to bit line BL1 through contact SC. Bit line BL1 extends in the second direction. The other one (D) of the two impurity areas S and D in each of the select transistors that use word line WL1, WL2, WL3 and WL4 as respective gate electrodes is connected to magnetoresistive element MTJ through contact BC.

Magnetoresistive element MTJ is a magnetoresistive element according to the above-described embodiments.

Bit line BL2 is connected to magnetoresistive element MTJ through contact TC. Bit line BL2 extends in the second direction. Interlayer insulating layers 21a and 21b are arranged between the semiconductor substrate 20 and bit line BL2.

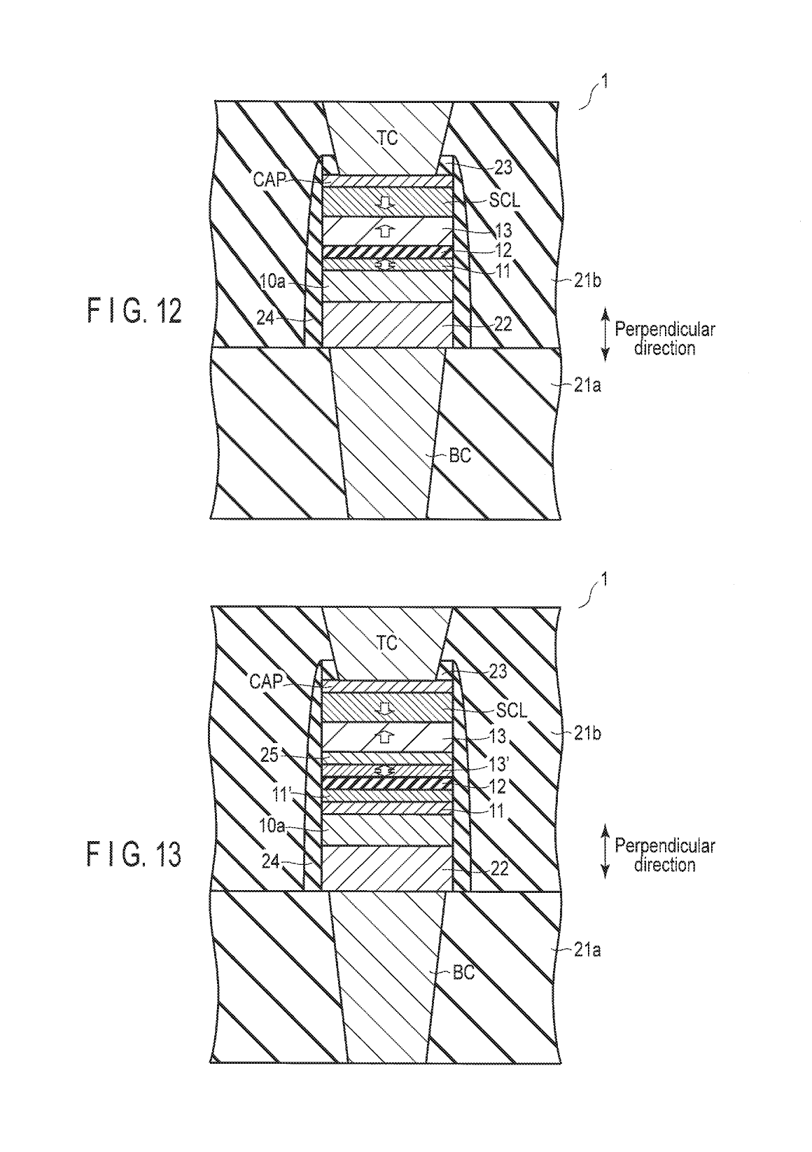

FIGS. 12 to 17 show examples of magnetoresistive element MTJ shown in FIGS. 10 and 11. In FIGS. 12 to 17, elements similar to those of FIGS. 10 and 11 are denoted by corresponding reference numbers.

FIG. 12 shows a first example of the magnetoresistive element.

The magnetoresistive element of this example comprises a metal layer 22, a foundation layer 10a, a first magnetic layer 11, a nonmagnetic layer 12, a second magnetic layer 13, a shift canceling layer SCL, and a cap layer CAP.

The metal layer 22 is provided on the contact BC. The metal layer 22 contains Pt, Ir, Ru, Cu, etc., for example. The metal layer 22 may contain high-melting-point metals, such as W and Ti. The metal layer 22 may have a function of controlling the orientations of layers arranged above itself.

The foundation layer 10a is provided on the metal layer 22. Since the foundation layer 10a is already described, no more description will be given thereof. The foundation layer 10a is formed of, for example, GaN.

The first magnetic layer 11 is provided on the foundation layer 10a. The first magnetic layer 11 is a storage layer having perpendicular and variable magnetization, for example. The nonmagnetic layer 12 is provided on the first magnetic layer 11. The nonmagnetic layer 12 is an insulating layer (tunnel barrier layer) having a thickness of, for example, 1 nm. or less. The second magnetic layer 13 is provided on the nonmagnetic layer 12. The second magnetic layer 13 is a reference layer having perpendicular and constant magnetization, for example.

The first and second magnetic layers 11 and 13 each comprise, for example, a CoFeB layer, a MgFeO layer, a FeB layer, or a laminated structure of these layers. In the case of a magnetoresistive element having perpendicular magnetization, it is desirable that the first and second magnetic layers 11 and 13 each comprise TbCoFe having perpendicular magnetic anisotropy, or an artificial lattice of stacked Co and Pt layers having perpendicular magnetic anisotropy, or

L₁₀-regulated FePt having perpendicular magnetic anisotropy. In this case, respective a CoFeB layer or a FeB layer as an interface layer may be interposed between the first maanetic layer 11 and the nonmagnetic layer 12, and between the nonmagnetic layer 12 and the second magnetic layer 13.

For example, it is preferable that a magnetic layer as the storage layer among the first and second magnetic layers 11, 13 includes CoFeB or FeB, and a magnetic layer as the reference layer among the first and second magnetic layers 11, 13 includes CoPt, CoNi, or CoPd.

The nonmagnetic layer 12 contains MgO, AlO, etc., for example. The nonmagnetic layer 12 may be formed of a nitride of Al, Si, Be, Mg, Ca, Sr, Ba, Sc La, Zr, Hf, etc.

The shift canceling layer SCL is provided on the second magnetic layer 13. Like the first and second magnetic layers 11 and 13, the shift canceling layer SCL is a magnetic layer. Further, the shift canceling layer SOL has magnetization of a direction opposite to that of the magnetization of the second magnetic layer 13. Thereby, the shift canceling layer SOL cancels shift of the magnetization reversal characteristics (represented by a hysteresis curve) of the first magnetic layer 11 due to a stray magnetic field from the second magnetic layer 13.

For example, it is preferable that the shift canceling layer SCL includes CoPt, CoNi, or CoPd. It is desirable that the shift canceling layer SCL has a structure of, for example, [Co/Pt]n in which n layers each comprising a Co layer and a Pt layer are stacked.

A nonmagnetic layer (formed of, for example, Pt, W, Ta, Ru, etc.) may be interposed between the second magnetic layer 13 and the shift canceling layer SCL for separating them.

The cap layer CAP is provided on the shift canceling layer SCL. The cap layer CAP includes Pt, W, Ru, Ta, etc., for example.

The above magnetoresistive element is covered by a protective layer 24. The protective layer 24 contains, for example, an aluminum oxide, a silicon oxide, a titanium oxide, a silicon nitride, etc.

FIG. 13 shows a second example of the magnetoresistive element.

The magnetoresistive element of this example differs from the magnetoresistive element of FIG. 12 in that the former additionally employs interface layers 11′ and 13′ and a buffer layer 25. The second example is similar in the other points to the magnetoresistive element of FIG. 12.

Interface layer 11′ is interposed between the first magnetic layer 11 and the nonmagnetic layer 12. Interface layer 13′ is interposed between the nonmagnetic layer 12 and the second magnetic layer 13. Interface lavers 11′ and 13° are formed of, for example, CoFeB, FeB.

The buffer layer 25 is interposed between interface layer 13′ and the second magnetic layer 13. The buffer layer 25 has a function of preventing the interdiffusion of elements between interface layer 13° and the second magnetic layer 13 during a heat treatment. The buffer layer 25 contains, for example, a high-melting-point metal, such as Ti, Ta, W, No, Nb, Zr or Hf, or its nitride or carbide.

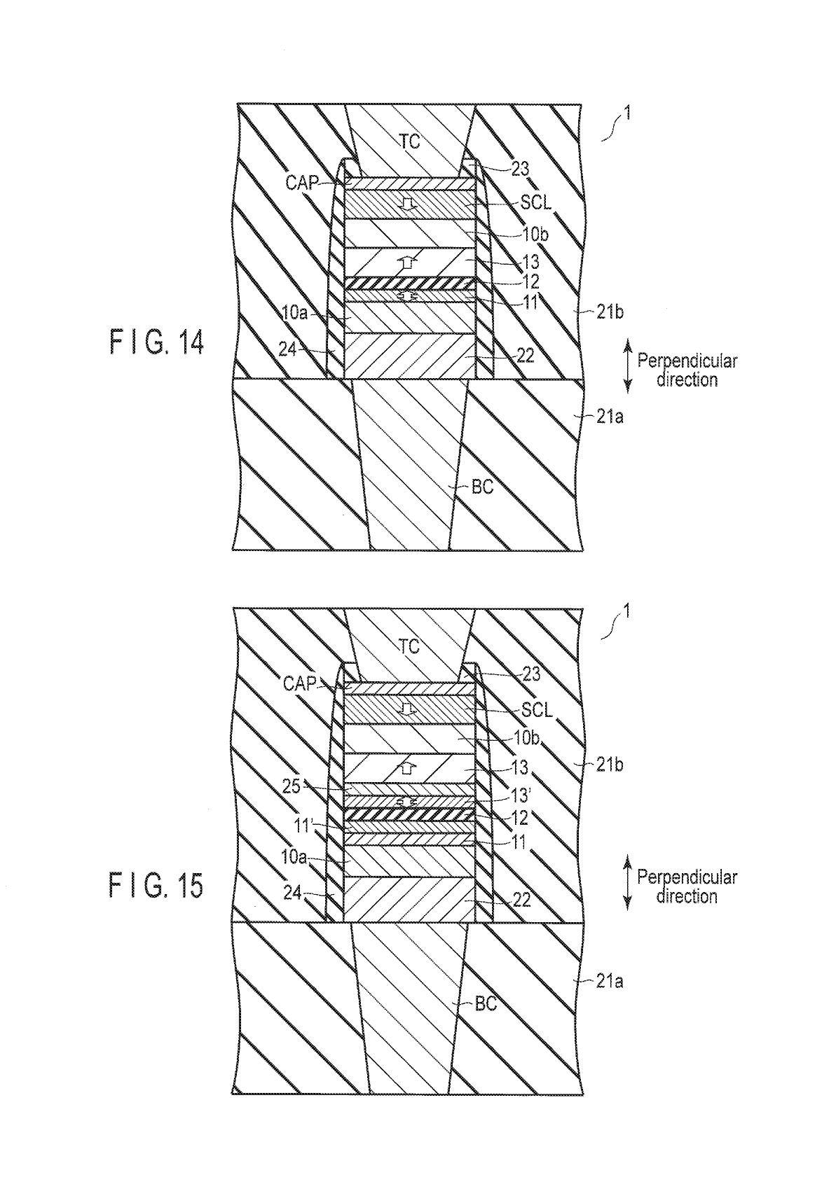

FIG. 14 shows a third example of the magnetoresistive element.

The magnetoresistive element of this example is a modification of the magnetoresistive element shown in FIG. 12.

The magnetoresistive element of this example differs from the magnetoresistive element of FIG. 12 in that the former additionally employs the upper layer 10b having perpendicular internal tensile stress. The upper layer 10b is interposed between the second magnetic layer 13 as a reference layer and the shift. canceling layer SCL. The third example is similar in the other points to the magnetoresistive element of FIG. 12.

By virtue of the above structure, the crystal structure or orientation of the second magnetic layer 13 can be controlled from above and below, whereby the magnetic anisotropy of the second magnetic layer 13 is enhanced.

FIG. 15 shows a fourth example of the magnetoresistive element.

The magnetoresistive element of this example is a modification of the magnetoresistive element shown in FIG. 13.

The magnetoresistive element of this example differs from the magnetoresistive element of FIG. 13 in that the former additionally employs the upper layer 10b having perpendicular internal tensile stress. The upper layer 10b is interposed between the second magnetic layer 13 as a reference layer and the shift canceling layer SCL. The third example is similar in the other points to the magnetoresistive element of FIG. 13.

By virtue of the above structure, the crystal structure or orientation of the second magnetic layer 13 can be controlled from above and below, whereby the magnetic anisotropy of the second magnetic layer 13 is enhanced.

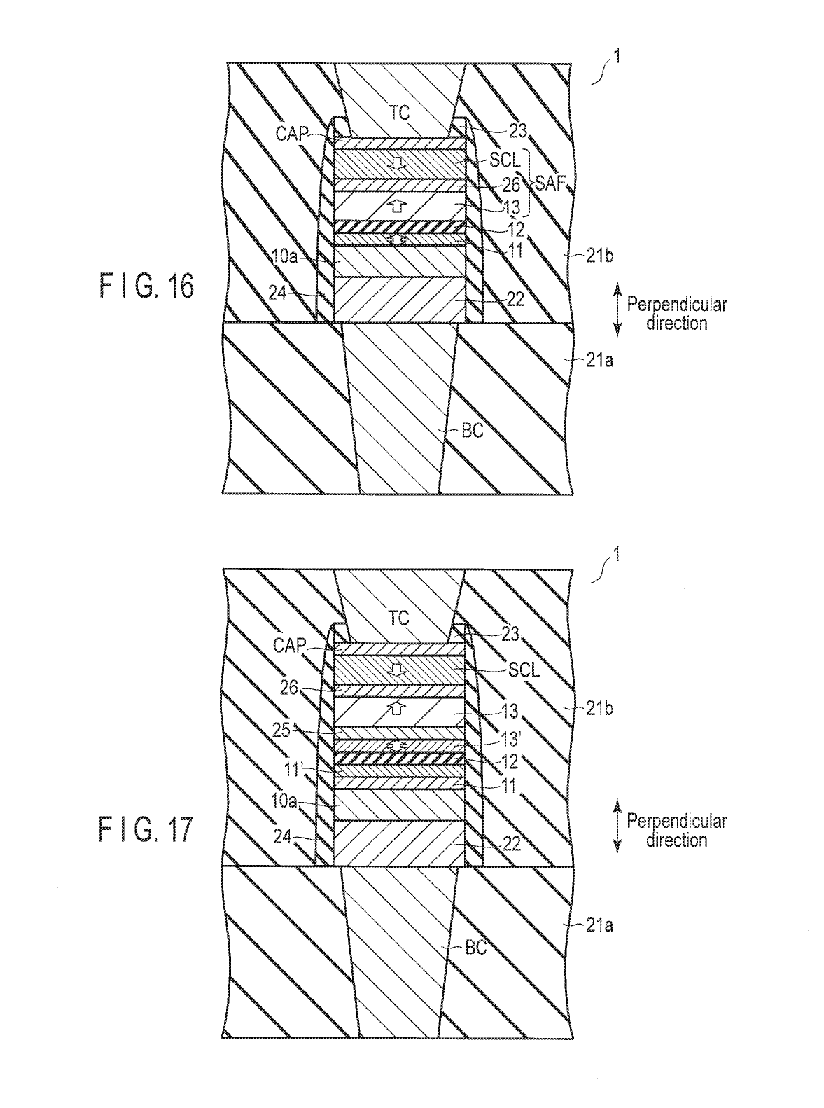

FIG. 16 shows a fifth example of the magnetoresistive element.

The magnetoresistive element of this example is another modification of the magnetoresistive element shown in FIG. 12.

The magnetoresistive element of this example differs from the magnetoresistive element of FIG. 12 in that the former additionally employs a nonmagnetic layer 26 between the second magnetic layer 13 as a reference layer and the shift canceling layer SCL. The fifth example is similar in the other points to the magnetoresistive element of FIG. 12.

The nonmagnetic layer 26 functions as a magnetic coupling layer for causing the second magnetic layer 13 and the shift canceling layer SCL to have anti-parallel magnetization. That is, the second magnetic layer 13 and the shift canceling layer SCL have synthetic antiferromagnetic (SAF) coupling.

Accordingly, the second magnetic layer 13 and the shift canceling layer SCL are fixed with their magnetization kept anti-parallel.

By virtue of the above structure, the magnetization of the second magnetic layer 13 and the shift canceling layer SCL is stabilized, thereby enhancing the characteristics of the magnetoresistive element.

FIG. 17 shows a sixth example of the magnetoresistive element.

The magnetoresistive element of this example is another modification of the magnetoresistive element shown in FIG. 13.

The magnetoresistive element of this example differs from the magnetoresistive element of FIG. 13 in that the former additionally employs a nonmagnetic layer 26 between the second magnetic layer 13 as a reference layer and the shift canceling layer SCL. The sixth example is similar in the other points to the magnetoresistive element of FIG. 13.

The nonmagnetic layer 26 functions as a magnetic coupling layer for causing the second magnetic layer 13 and the shift canceling layer SCL to have anti-parallel magnetization. That is, the second magnetic layer 13 and the shift canceling layer SCL have synthetic antiferromagnetic (SAP) coupling.

Accordingly, the second magnetic layer 13 and the shift canceling layer SOL are fixed with their magnetization kept anti-parallel.

By virtue of the above structure, the magnetization of the second magnetic. layer 13 and the shift canceling layer SCL is stabilized, thereby enhancing the characteristics of the magnetoresistive element.

(Conclusion)

As described above, according to the embodiments, the characteristics (MR ratio, flux reversal current, retention, etc.) of the magnetoresistive element can be enhanced by enhancing the perpendicular magnetic anisotropy of the storage layer and the reference layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is

1. A magnetoresistive element comprising:
a first layer including a material as one of a nitride, an oxide, a carbide and a boride;
a second layer as a magnetic layer on the first layer;
a third layer as a nonmagnetic layer on the second layer; and
a fourth layer as a magnetic layer on the third layer, magnetization directions of the second and fourth layers being a perpendicular direction in which the first, second, third and fourth layers are stacked,
wherein the first layer is thinner than a crystal grain size of the first layer in the perpendicular direction.

2. The element of claim 1, wherein the material has an internal tensile stress in the perpendicular direction.

3. The element of claim I, wherein the nonmagnetic layer has a NaCl-crystal structure, and the material has a hexagonal close-packed (hcp) crystal structure or a wurtzite crystal structure.

4. The element of claim 3, wherein the nonmagnetic layer is oriented in a (001)-direction, and. the material is oriented in a (0001)-direction.

5. The element of claim 1, wherein the first layer comprises regions different in at least one of a state, a material, a composition ratio and a conductivity.

6. The element of claim. 1, further comprising an interface layer between the first and second layers.

7. The element of claim 6, wherein the interface layer includes one of Fe and FeO.

8. The element of claim 1, wherein the first layer includes GaN, AlN, or a mixture thereof, the first and second magnetic layers include CoFeB, and the nonmagnetic layer includes MgO.

9. The element of claim 1, further comprising a fifth layer as a magnetic layer on the fourth laver, a magnetization direction of the fifth layer being the perpendicular direction,
wherein the second layer is a storage layer, the fourth layer is a reference layer, the fifth layer is a shift canceling layer, and magnetization directions of the fourth and fifth layers is opposite directions each other.

10. A method of manufacturing the element of claim 1, the method comprising:
forming a predetermined layer on the first layer;
crystallizing the first layer by a first heat treatment;
removing the predetermined layer by an etch back;
forming the second layer on the first layer;
forming the third layer on the second layer;
forming the fourth layer on the third layer; and
crystallizing the second and fourth layers by a second heat treatment.

11. The method of claim 10, wherein the predetermined layer has a crystal structure or orientation similar to a crystal structure or orientation of the third layer.

12. The method of claim 10, wherein the first layer is thinned by the etch. back.

13. The method of claim 10, wherein the first heat treatment is performed in a gaseous atmosphere including at least one of nitrogen, oxygen, carbon and boron.

14. The method of claim 10, wherein the second layer is crystallized based on a crystal structure or orientation of the first and third layers.

15. A magnetoresistive element comprising:
a first layer as a magnetic layer;
a second layer as a nonmagnetic layer on the first layer;
a third layer as a magnetic layer on the second layer, magnetization directions of the first and third layers being a perpendicular direction in which the first, second and third layers are stacked; and
a fourth layer on the third layer, the fourth layer including a material as one of a nitride, an oxide, a carbide and a boride.

16. The element of claim 15, wherein the material has an internal tensile stress in the perpendicular direction.

17. The element of claim 15, wherein the nonmagnetic layer has a NaCl-crystal structure, and the material has a hexagonal close-packed (hop) crystal structure or a wurtzite crystal structure.

18. The element of claim 17, wherein the nonmagnetic layer is oriented in a (001)-direction, and the material is oriented in a (0001)-direction.

19. The element of claim 15, wherein the fourth layer comprises regions different in at least one of a state, a material, a composition ratio and a conductivity.

20. The element of claim 15, further comprising an interface layer between the third and fourth layers.
